(19) United States
(12) Patent Application Publication
(10) Pub. No.: US 2026/0274594 A1
(43) Pub. Date: Sep. 17, 2026

(54) LINEAR CONVEYANCE SYSTEM

(71) Applicant: Mitsubishi Electric Corporation, Tokyo (JP)

(72) Inventors: Yuichiro NAKAMURA, Tokyo (JP); Kenji TAKAHASHI, Tokyo (JP)

(73) Assignee: Mitsubishi Electric Corporation, Tokyo (JP)

(21) Appl. No.: 19/168,952

(22) PCT Filed: Apr. 24, 2023
(86) PCT No.: PCT/JP2023/016134

§ 371 Date: Sep. 25, 2025

(51) Int. Cl. B65G 54/02; B65G 47/64

(52) U.S. Cl. CPC B65G 54/02; B65G 47/64

(57) ABSTRACT

A linear conveyance system of the present disclosure includes a mover having a magnet disposed on side faces thereof, and a conveyance path in which a first module having a plurality of coils and configured to move the mover by an electromagnetic force of the plurality of coils and a second module formed of a magnetic material without coils are arranged along a traveling direction of the mover. The conveyance path includes a non-branching portion in which the first module is disposed on one side of the side faces of the mover, and a branching portion in which the first module is disposed on one side of the side faces of the mover and the second module is disposed on the other side thereof.

### TECHNICAL FIELD

The present disclosure relates to a linear conveyance system using thrust of a linear motor.

### BACKGROUND ART

A technology is known in which a mover equipped with a plurality of magnets moves along a linear guide composed of multiple stator modules, allowing for the branching and merging in a conveyance path through an electromagnetic force. For example, Patent Document 1 discloses a configuration in which, in a section where a conveyance path branches, stator modules having coils are arranged on both sides of the mover, and a lateral force for moving the mover in the branching direction is applied by energizing the coil of the stator module on one side.

### PRIOR ART DOCUMENT

### Patent Document

[Patent Document 1] National Publication of International Patent Application No. 2016-531534

### SUMMARY OF THE INVENTION

### Problem to be Solved by the Invention

However, in the conventional linear conveyance system, since the stator modules having the coils are disposed on both sides of the mover in the section where the conveyance path branches, there is a problem of an increase in the weight of the linear conveyance system.

The present disclosure has been made to solve the above-described problem, and an object of the present disclosure is to provide a linear conveyance system that prevents an increase in weight even when a conveyance path branches.

### Means for Solving the Problem

A linear conveyance system according to the present disclosure includes a mover having a magnet disposed on side faces thereof, and a conveyance path in which a first module having a plurality of coils and configured to move the mover by an electromagnetic force of the plurality of coils and a second module formed of a magnetic material without coils are arranged along a traveling direction of the mover. The conveyance path includes a non-branching portion in which the first module is disposed on one side of the side faces of the mover, and a branching portion in which the first module is disposed on one side of the side faces of the mover and the second module is disposed on the other side of the side faces of the mover.

### Effects of the Invention

According to the linear conveyance system of the present disclosure, the second module having no coils is used on one side of the side faces of the mover in the branching portion of the conveyance path, and thus an effect of preventing an increase in weight is achieved.

### BRIEF DESCRIPTION OF THE DRAWINGS

FIG. 1 is a schematic configuration diagram showing a linear conveyance system according to Embodiment 1 of the present disclosure.

FIG. 2 is a cross-sectional view showing a first module and a second module of the linear conveyance system according to Embodiment 1 of the present disclosure.

FIG. 3 is a cross-sectional view showing a case where a mover travels in a positive X direction and is attracted in a negative Y direction at a branching portion of the linear conveyance system according to Embodiment 1 of the present disclosure.

FIG. 4 is a cross-sectional view showing a case where the mover travels in a negative X direction and is attracted in a positive Y direction at the branching portion of the linear conveyance system according to Embodiment 1 of the present disclosure.

FIG. 5 is a cross-sectional view showing a case where the mover travels in the positive X direction and is attracted in the positive Y direction at the branching portion of the linear conveyance system according to Embodiment 1 of the present disclosure.

FIG. 6 is a cross-sectional view showing a case where the mover travels in the negative X direction and is attracted in the negative Y direction at the branching portion of the linear conveyance system according to Embodiment 1 of the present disclosure.

FIG. 7 is a cross-sectional view showing a first module and a second module of a linear conveyance system according to Embodiment 2 of the present disclosure.

FIG. 8 is a cross-sectional view showing a case where the mover travels in the positive X direction and is attracted in the negative Y direction at the branching portion of the linear conveyance system according to Embodiment 2 of the present disclosure.

FIG. 9 is a cross-sectional view showing a case where the mover travels in the negative X direction and is attracted in the positive Y direction at the branching portion of the linear conveyance system according to Embodiment 2 of the present disclosure.

FIG. 10 is a cross-sectional view showing a case where the mover travels in the positive X direction at the branching portion and is attracted in the positive Y direction before passing through a step in the linear conveyance system according to Embodiment 2 of the present disclosure.

FIG. 11 is a cross-sectional view showing a case where the mover travels in the positive X direction in a branching portion and is attracted in the positive Y direction after passing through the step in the linear conveyance system according to Embodiment 2 of the present disclosure.

FIG. 12 is a cross-sectional view showing a case where the mover travels in the negative X direction at the branching portion and is attracted in the negative Y direction before passing through the step in the linear conveyance system according to Embodiment 2 of the present disclosure.

FIG. 13 is a cross-sectional view showing a case where the mover travels in the negative X direction at the branching portion passes over a step and is attracted in the negative Y direction in the linear conveyance system according to Embodiment 2 of the present disclosure,

FIG. 14 is a cross-sectional view showing a first module and a second module of a linear conveyance system according to Embodiment 3 of the present disclosure.

FIG. 15 is a cross-sectional view showing a first module and a second module of a linear conveyance system according to Embodiment 4 of the present disclosure.

FIG. 16 is a cross-sectional view showing a first module and a second module of a linear conveyance system according to Embodiment 5 of the present disclosure.

FIG. 17 is a cross-sectional view showing a first module and a second module of a linear conveyance system according to Embodiment 6 of the present disclosure.

### DETAILED DESCRIPTION OF THE INVENTION

Hereinafter, a linear conveyance system according to embodiments will be described in detail with reference to the drawings.

### Embodiment 1

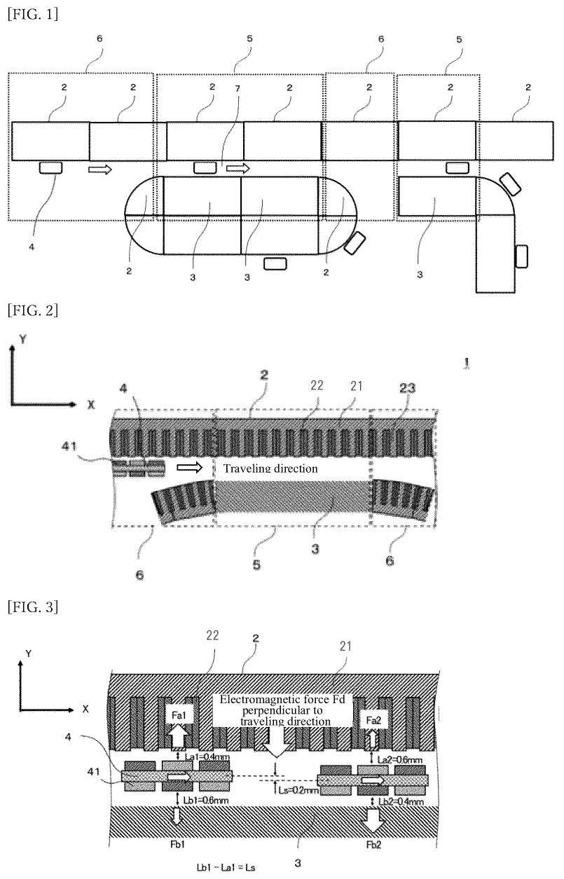

FIG. 1 is a schematic configuration diagram showing a linear conveyance system according to Embodiment 1 of the present disclosure. As shown in FIG. 1, in the present embodiment, the traveling direction of a mover 4 and the direction orthogonal to the traveling direction of the mover 4 are defined as the X direction and the Y direction, respectively, and the right side in the X direction is defined as the positive direction and the upper side in the Y direction is defined as the positive direction. Note that, although the coordinate system as described above is set for convenience of description, the X direction and the Y direction may be set as appropriate depending on the configuration of the linear conveyance system.

A linear conveyance system 1 includes a mover 4 having magnets 41 disposed on its side faces, and a conveyance path 7 in which a first module 2 having a plurality of coils 22 and configured to move the mover 4 by an electromagnetic force of the plurality of coils 22 and a second module 3 formed of a magnetic material without coils are arranged along a traveling direction of the mover 4. The conveyance path 7 includes a non-branching portion 6 in which the first module 2 is disposed on one side of the side faces of the mover 4, and a branching portion 5 in which the first module 2 is disposed on one side of the side faces of the mover 4 and the second module 3 is disposed on the other side thereof.

FIG. 2 is a cross-sectional view showing the first module and the second module of the linear conveyance system according to Embodiment 1 of the present disclosure. As shown in FIG. 2, the first module 2 includes an iron core 21 and the plurality of coils 22. The iron core 21 has a plurality of teeth 23, and each of the plurality of coils 22 is wound around one of the plurality of teeth 23. The second module 3 is formed of a magnetic material, but does not have coils. The second module 3 has a flat shape such that a distance from the magnets 41 of the mover 4 is constant, and is formed of, for example, a laminated steel plate in order to minimize a loss during the drive of the mover 4. Although the first module 2 has the coils in this example, the first module 2 and the second module 3 may be replaced with each other, so that the first module 2 is formed only of a magnetic material and the second module 3 is formed of an iron core and coils.

The mover 4 is located on one side of the lateral sides of the first module 2 in the non-branching portion 6, and moves by receiving an electromagnetic force from the first module 2. In the branching portion 5 of the conveyance path 7, the mover 4 is positioned between the first module 2 and the second module 3 and is driven by the electromagnetic force from the plurality of coils 22 included in the first module 2. Here, as shown in FIG. 2, the traveling direction of the mover 4 is the X direction, and the direction perpendicular to the traveling direction is the Y direction. Each of a plurality of the movers 4 is independently controlled in the conveyance path 7. Although not shown in the figure, a motor drive control device supplies a current to each of the coils 22 of the first module 2 located near the mover 4. For example, the current is not three phase UVW currents but each coil 22 is supplied with an independently controlled single-phase AC current having an arbitrary waveform.

The mover 4 has a plurality of the magnets 41 disposed on both side faces. As shown in FIG. 2, the magnets 41 on both side faces of the mover 4 are arranged such that the magnetic pole directions of the magnets 41 in the Y direction of the mover 4 are reversed. In Embodiment 1, the arrangement of the magnets 41 in the Y direction may be the same or the arrangement of the magnets 41 in the Y direction may be shifted in the X direction.

FIG. 3 is a cross-sectional view showing a case where the mover travels in the positive X direction and is attracted in the negative Y direction at the branching portion of the linear conveyance system according to Embodiment 1 of the present disclosure. In the branching portion 5 of the conveyance path 7, the mover 4 is located between the first module 2 and the second module 3. Each of a plurality of the magnets 41 included in mover 4 faces the first module 2 or the second module 3. When the coils 22 of the first module 2 are energized, an electromagnetic force (driving force) in a direction parallel to the traveling direction acts on the mover 4. In the branching portion 5, in order to guide the mover 4 to a selected path, the coils 22 in the vicinity of the mover 4 are energized, and the first module 2 applies an electromagnetic force (branching lateral force) in a direction perpendicular to the traveling direction of the mover 4. Accordingly, the first module 2 moves the mover 4. By energizing at least two or more coils 22, any desired driving force and branching lateral force can be generated simultaneously.

As shown in FIG. 3, it is assumed that, when the mover 4 moves from the negative X direction to the positive X direction in the branching portion 5 and a magnetic attraction force Fa1 between the first module 2 and the mover 4 is larger than a magnetic attraction force Fb1 between the second module 3 and the mover 4, a path in a direction in which the magnetic attraction force Fb1 increases is selected by a user of the linear conveyance system 1. The linear conveyance system 1 causes an electromagnetic force Fd from the positive Y direction to the negative Y direction to act on the mover 4. Note that the gap between the mover 4 and the first module 2 and the gap between the mover 4 and the second module 3 are an example, and they are not limited to these values. Accordingly, a distance Lb2 between the second module 3 and the mover 4 in the negative Y direction becomes smaller than a distance Lb1 between the second module 3 and the mover 4 in the Y direction before the electromagnetic force acts. With this action, the linear conveyance system 1 can cause the mover 4 to move along the path in a direction in which the magnetic attraction force Fb1 between the second module 3 and mover 4 increases. After the path is selected by the branching portion 5, the mover 4 moves by receiving the electromagnetic force Fd from the first module 2 of the non-branching portion 6. That is, the relationships of the following Expression (1) to Expression (5) are satisfied in a distance Ls of the mover 4 moved by the action of the electromagnetic force, distances La1 and La2 between the first module 2 and the mover 4 before and after the electromagnetic force acts, the distances Lb1 and Lb2 between the second module 3 and the mover 4 before and after the electromagnetic force acts, the electromagnetic force Fd, the magnetic attraction forces Fa1 and Fa2 before and after the electromagnetic force between the first module 2 and the mover 4 acts, and the magnetic attraction forces Fb1 and Fb2 before and after the electromagnetic force between the first module 2 and the mover 4 acts.

$$\begin{matrix}[ Formula 1 ] & \\ Lb 1 - La 1 = La 2 - Lb 2 = Ls & ( 1 )\end{matrix}$$

$$La 2 - La 1 = Lb 1 - Lb 2 = Ls \qquad ( 2 )$$

$$Fa 1 + Fb 1 > 0 \qquad ( 3 )$$

$$Fa 1 + Fb 1 + Fd < 0 \qquad ( 4 )$$

$$Fa 2 + Fb 2 < 0 \qquad ( 5 )$$

Note that, in Expression (1) to Expression (5), the magnetic attraction force Fb2 between the second module 3 and the mover 4 in the negative Y direction is larger than the magnetic attraction force Fa2 between the first module 2 and the mover 4 in the positive Y direction after the electromagnetic force acts, but the relationship of the distance Lb2 and the distance La2 between the first module 2 and the mover 4 in the positive Y direction may be La2<Lb2 depending on the shape of the second module 3. As described above, in the linear conveyance system 1 according to Embodiment 1 of the present disclosure, when the mover 4 moves from the negative X direction to the positive X direction at the branching portion 5, regarding the force acting on the mover in the direction perpendicular to the traveling direction 4, the electromagnetic force due to the second module 3 becomes larger than the electromagnetic force due to the first module 2, and thus the distance perpendicular to the traveling direction between the mover 4 and the second module 3 is reduced.

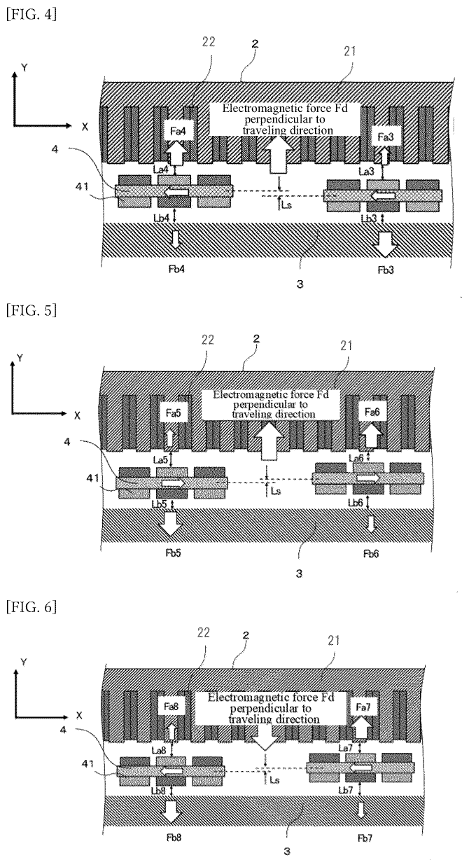

FIG. 4 is a cross-sectional view showing a case where the mover travels in the negative X direction and is attracted in the positive Y direction at the branching portion of the linear conveyance system according to Embodiment 1 of the present disclosure. As shown in FIG. 4, it is assumed that, when the mover 4 moves in the negative X direction at the branching portion 5 and a magnetic attraction force Fb3 between the second module 3 and the mover 4 is larger than a magnetic attraction force Fa3 between the first module 2 and the mover 4, a path in a direction in which the magnetic attraction force Fa3 increases is selected by a user of the linear conveyance system 1. The linear conveyance system 1 causes an electromagnetic force to act on the mover 4 from the negative Y direction to the positive Y direction. Accordingly, a distance Lb4 between the second module 3 and the mover 4 in the negative Y direction after the electromagnetic force acts is larger than a distance Lb3 between the second module 3 and the mover 4 in the negative Y direction before the electromagnetic force acts. With this action, the linear conveyance system 1 can cause the mover 4 to move along the path in a direction in which the magnetic attraction force between the first module 2 and the mover 4 increases. After the path is selected by the branching portion 5, the mover 4 moves by receiving the electromagnetic force from the first module 2 of the non-branching portion 6. That is, at this time, the relationships of the following Expression (6) to Expression (10) are satisfied in the distance Ls of the mover 4 moved by the action of the electromagnetic force, the distances La3 and La4 between the first module 2 and the mover 4 before and after the electromagnetic force acts, the distances Lb3 and Lb4 between the second module 3 and the mover 4 before and after the electromagnetic force acts, the electromagnetic force Fd, the magnetic attraction forces Fa3 and Fa4 before and after the electromagnetic force between the first module 2 and the mover 4 acts, and the magnetic attraction forces Fb3 and Fb4 before and after the electromagnetic force between the first module 2 and the mover 4 acts.

$$\begin{matrix}[ Formula 2 ] & \\ La 3 - Lb 3 = Lb 4 - La 4 = Ls & ( 6 )\end{matrix}$$

$$La 3 - La 4 = Lb 4 - Lb 3 = Ls \qquad ( 7 )$$

$$Fa 3 + Fb 3 < 0 \qquad ( 8 )$$

$$Fa 3 + Fb 3 + Fd > 0 \qquad ( 9 )$$

$$Fa 4 + Fb 4 > 0 \qquad ( 10 )$$

In Expression (6) to Expression (10), the magnetic attraction force Fb3 between the second module 3 and the mover 4 in the negative Y direction is larger than the magnetic attraction force Fa3 between the first module 2 and the mover 4 in the positive Y direction before the electromagnetic force acts, but the relationship of the distance Lb3 and the distance La3 between the first module 2 and the mover 4 in the positive Y direction may be La3<Lb3 depending on the shape of the second module 3. As described above, in the linear conveyance system 1 according to Embodiment 1 of the present disclosure, when the mover 4 moves from the positive X direction to the negative X direction at the branching portion 5, regarding the force acting on the mover in the direction perpendicular to the traveling direction 4, the electromagnetic force due to the second module 3 is smaller than the electromagnetic force due to the first module 2, and thus the distance perpendicular to the traveling direction between the mover 4 and the second module 3 is increased.

FIG. 5 is a cross-sectional view showing a case where the mover travels in the positive X direction and is attracted in the positive Y direction at the branching portion of the linear conveyance system according to Embodiment 1 of the present disclosure. As shown in FIG. 5, it is assumed that, when the mover 4 moves in the positive X direction in the branching portion 5 and a magnetic attraction force Fb5 between the second module 3 and the mover 4 is larger than a magnetic attraction force Fa5 between the first module 2 and the mover 4, a path in a direction in which the magnetic attraction force Fa5 increases is selected by a user of the linear conveyance system 1. The linear conveyance system 1 causes an electromagnetic force to act on the mover 4 from the negative Y direction to the positive Y direction. Accordingly, a distance Lb6 between the second module 3 and the mover 4 after the electromagnetic force acts is larger than a distance Lb5 between the second module 3 and the mover 4 in the negative Y direction before the electromagnetic force acts. With this action, the linear conveyance system 1 can cause the mover 4 to move along the path in a direction in which the magnetic attraction force between the first module 2 and the mover 4 increases. After the path is selected after the branching portion 5 is passed through, the mover 4 moves by receiving the electromagnetic force from the first module 2 of the non-branching portion 6. At this time, the relationships of the following Expression (11) to Expression (15) are satisfied in the distance Ls of the mover 4 moved by the action of the electromagnetic force, the distances La5 and La6 between the first module 2 and the mover 4 before and after the electromagnetic force acts, the distances Lb5 and Lb6 between the second module 3 and the mover 4 before and after the electromagnetic force acts, the electromagnetic force Fd, the magnetic attraction forces Fa5 and Fa6 before and after the electromagnetic force between the first module 2 and the mover 4 acts, and the magnetic attraction forces Fb5 and Fb6 before and after the electromagnetic force between the first module 2 and the mover 4 acts.

$$\begin{matrix}[ Formula 3 ] & \\ La 5 - Lb 5 = Lb 6 - La 6 = Ls & ( 11 )\end{matrix}$$

$$La 5 - La 6 = Lb 6 - Lb 5 = Ls \qquad ( 12 )$$

$$Fa 5 + Fb 5 < 0 \qquad ( 13 )$$

$$Fa 5 + Fb 5 + Fd > 0 \qquad ( 14 )$$

$$Fa 6 + Fb 6 > 0 \qquad ( 15 )$$

Note that, in Expression (11) to Expression (15), the magnetic attraction force Fb5 of the magnets 41 in the negative Y direction between the second module 3 and the mover 4 is larger than the magnetic attraction force Fa5 of the magnets 41 in the positive Y direction between the first module 2 and the mover 4 before the electromagnetic force acts, but the relationship between the distance La5 in the positive Y direction from the first module 2 to the magnets 41 of the mover 4 and the distance Lb5 in the negative Y direction from the first module 2 to the magnets 41 of the mover 4 may be La5<Lb5 depending on the shape of the second module. As described above, in the linear conveyance system 1 according to Embodiment 1 of the present disclosure, when the mover 4 moves from the negative X direction to the positive X direction at the branching portion 5, regarding the force acting on the mover in the direction perpendicular to the traveling direction 4, the electromagnetic force due to the second module 3 becomes smaller than the electromagnetic force due to the first module 2, and thus the distance perpendicular to the traveling direction between the mover 4 and the second module 3 is increased.

FIG. 6 is a cross-sectional view showing a case where the mover travels in the negative X direction and is attracted in the negative Y direction at the branching portion of the linear conveyance system according to Embodiment 1 of the present disclosure. As shown in FIG. 6, it is assumed that, in the branching portion 5, when the mover 4 moves in the negative X direction and a magnetic attraction force Fa7 between the first module 2 and the mover 4 in the positive Y direction is larger than a magnetic attraction force Fb7 between the second module 3 and the mover in the negative Y direction, a path in a direction in which the magnetic attraction force Fb7 between the second module 3 and the mover 4 increases is selected by a user of the linear conveyance system 1. The linear conveyance system 1 causes an electromagnetic force from the positive Y direction to the negative Y direction to act on the mover 4. Accordingly, a distance Lb8 between the second module 3 and the mover 4 in the negative Y direction after the electromagnetic force acts is smaller than a distance Lb7 between the second module 3 and the mover 4 in the negative Y direction before the electromagnetic force acts. With this action, the linear conveyance system 1 can cause the mover 4 to move along the path in a direction in which the magnetic attraction force in the negative Y direction between the second module 3 and the mover 4 increases. After the path is selected in the branching portion 5, the mover 4 moves by receiving the electromagnetic force from the first module 2 of the non-branching portion 6. At this time, the relationships of the following Expression (16) to Expressions (20) are satisfied in the distance Ls of the mover 4 moved by the action of the electromagnetic force, the distances La7 and La8 between the first module 2 and the mover 4 before and after the electromagnetic force acts, the distances Lb7 and Lb8 between the second module 3 and the mover 4 before and after the electromagnetic force acts, the electromagnetic force Fd, the magnetic attraction forces Fa7 and Fa8 before and after the electromagnetic force between the first module 2 and the mover 4 acts, and the magnetic attraction forces Fb7 and Fb8 before and after the electromagnetic force between the first module 2 and the mover 4 acts.

$$\begin{matrix}[ Formula 4 ] & \\ Lb 7 - La 7 = Lb 8 - La 8 = Ls & ( 16 )\end{matrix}$$

$$La 8 - La 7 = Lb 7 - Lb 8 = Ls \qquad ( 17 )$$

$$Fa 7 + Fb 7 > 0 \qquad ( 18 )$$

$$Fa 7 + Fb 7 + Fd < 0 \qquad ( 19 )$$

$$Fa 8 + Fb 8 < 0 \qquad ( 20 )$$

In Expression (16) to Expression (20), the magnetic attraction force Fb8 between the second module 3 and the mover 4 in the negative Y direction is larger than the magnetic attraction force Fa8 between the first module 2 and the mover 4 in the positive Y direction before the electromagnetic force acts, but the relationship between the distance La8 from the first module 2 to the mover 4 in the positive Y direction and the distance Lb8 from the first module 2 to the mover 4 in the negative Y direction may be La8<Lb8 depending on the shape of the second module 3. As described above, in the linear conveyance system 1 according to Embodiment 1 of the present disclosure, when the mover 4 moves from the positive X direction to the negative X direction at the branching portion 5, regarding the force acting on the mover in the direction perpendicular to the traveling direction 4, the electromagnetic force due to the second module 3 becomes larger than the electromagnetic force due to the first module 2, and thus the distance perpendicular to the traveling direction between the mover 4 and the second module 3 is reduced.

As described above, the linear conveyance system 1 according to Embodiment 1 of the present disclosure includes the mover 4 having the magnets 41 arranged on side faces, and the conveyance path 7 in which the first module 2 and the second module 3 are arranged in multiple locations along a traveling direction of the mover 4, the first module 2 having the plurality of coils 22 and allowing the mover 4 to move by the electromagnetic force by the plurality of coils 22, the second module 3 formed of a magnetic material and having no coil. The conveyance path 7 includes the non-branching portion 6 in which the first module 2 is disposed on one side of the side faces of the mover 4, and the branching portion 5 in which the first module 2 is disposed on one side of the faces of the mover 4 and the second module 3 is disposed on the other side thereof. In a conventional linear conveyance system, even when a path branches, coils similar to those in a section where the path does not branch are disposed, but in the linear conveyance system 1 according to the present disclosure, the second module 3 is formed of only a magnetic material, and coils are not wound. Therefore, according to the linear conveyance system of Embodiment 1 of the present disclosure, even when the conveyance path 7 branches, the second module 3 is used on one side of the side faces of the mover 4 at the branching portion 5, and thus, effects of preventing an increase in weight in the linear conveyance system 1 and preventing the linear conveyance system 1 from increasing in size are achieved.

In addition, by using the second module 3 having no coil at the branching portion, the number of inverters for energizing the coils can be reduced as compared with the case where the first module 2 is disposed on both sides, and an increase in the weight of the linear conveyance system 1 can be prevented, and an effect of preventing the linear conveyance system 1 from becoming larger is obtained.

In addition, according to the linear conveyance system 1 of the present disclosure, the wiring work is reduced due to the reduction of the coils, and the assembly of the motor is facilitated. Furthermore, since the shape of the second module 3 having no coil can be made smaller than the shape of the first module 2, the weight of the second module 3 can also be reduced. Note that the shape of the second module 3 may be the same as the shape of the iron core of the first module 2, the second module 3 may have a plurality of teeth in order to reduce cogging thrust, or the teeth of the first module and the teeth of the second module may be shifted in phase.

### Embodiment 2

In Embodiment 2, the same reference numerals are used for the same components as those in Embodiment 1 of the present disclosure, and the description of the same or corresponding parts will be omitted. Hereinafter, a linear conveyance system 1b according to Embodiment 2 will be described with reference to the drawings.

FIG. 7 is a cross-sectional view showing a first module and a second module of a linear conveyance system according to Embodiment 2 of the present disclosure. As shown in FIG. 7, in the linear conveyance system 1b according to Embodiment 2, in addition to the configuration of Embodiment 1, a step 8 in a direction perpendicular to the traveling direction is provided in the second module 31. The step 8 is provided such that, in a range where the second module 31 and the mover 4 face each other, an average distance from the surface of the second module 31 to the surface of the magnets 41 changes depending on a position of the second module 31 in the X direction. Although the distance between the second module 31 and the magnets 41 varies depending on the position in FIG. 7, the shape of the iron core 21 of the first module 2 may be changed, or both the shapes of the iron core 21 of the first module 2 and the second module 31 may be changed.

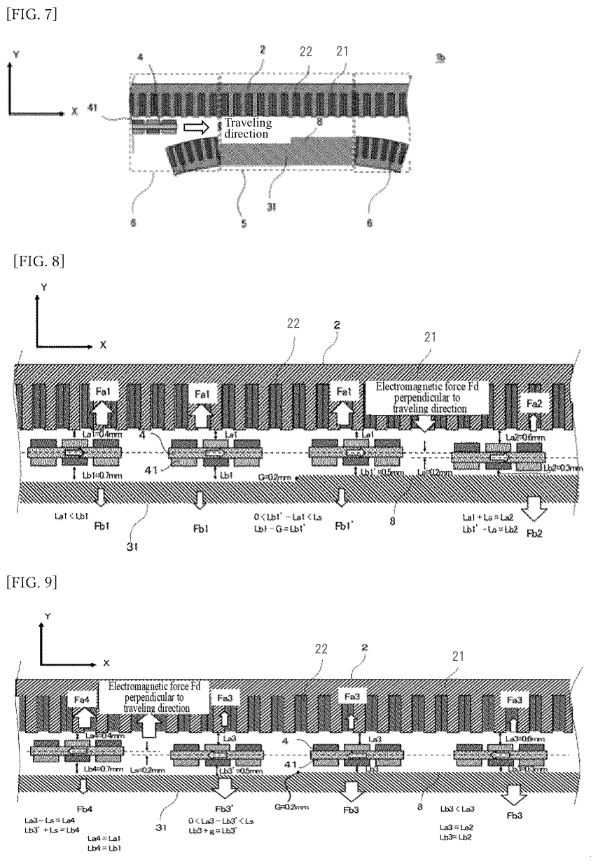

FIG. 8 is a cross-sectional view showing a case where the mover travels in the positive X direction and is attracted in the negative Y direction at the branching portion of the linear conveyance system according to Embodiment 2 of the present disclosure. As shown in FIG. 8, the second module 31 has the step 8 in a direction perpendicular to the traveling direction, that is, in the Y direction. Due to the step 8, the distance of the mover 4 on the side facing the second module 31 is smaller than the distance on the side facing the first module 2. In FIG. 8 it is assumed that, when mover 4 moves in the positive X direction at the branching portion 5 and the magnetic attraction force Fa1 between the first module 2 and the mover 4 is larger than the magnetic attraction force Fb1 between the second module 31 and the mover 4 in the Y direction, a user of the linear conveyance system 1b selects a path in a direction in which the magnetic attraction force Fb1 increases. At this time, the relationships of the following Expression (21) to Expression (26) are satisfied in the distance Ls of the mover 4 moved by the action of the electromagnetic force, the distances La1 and La2 between the first module 2 and the mover 4 before and after the electromagnetic force acts, the distances Lb1 and Lb2 between the second module 3 and the mover 4 before and after the electromagnetic force acts, the electromagnetic force Fd, the magnetic attraction forces Fa1 and Fa2 before and after the electromagnetic force between the first module 2 and the mover 4 acts, and the magnetic attraction forces F1 and Fb2 before and after the electromagnetic force between the first module 2 and the mover 4 acts.

$$\begin{matrix}[ Formula 5 ] & \\ Lb 1 - G = Lb {1}^{′} & ( 21 )\end{matrix}$$

$$Lb 1 - La 1 > Ls > Lb {1}^{′} - La 1 > 0 \qquad ( 22 )$$

$$La 2 - La 1 = Lb {1}^{′} - Lb 2 = Ls \qquad ( 23 )$$

$$Fa 1 + Fb 1 > Fa 1 + Fb 1 ' > 0 \qquad ( 24 )$$

$$Fa 1 + Fb {1}^{′} + Fd < 0 \qquad ( 25 )$$

$$Fa 2 + Fb 2 < 0 \qquad ( 26 )$$

The linear conveyance system 1b causes an electromagnetic force from the positive Y direction to the negative Y direction to act in a region after the mover 4 passes through the step 8. A distance Lb1′ between the second module 31 and the mover 4 after the step 8 is passed through is smaller than the distance Lb1 between the second module 31 and the mover 4 before the step 8 is passed through. A magnetic attraction force Fb1′ after the step 8 is passed through is large as |Fb1′|>|Fb1|, but from the Expression (24), before the electromagnetic force acts, the relationship of Fa1+Fb1′>0 is satisfied, and the magnetic attraction force in the positive Y direction is large. When the electromagnetic force acts, the distance Lb2 between the second module 31 and the mover 4 after the electromagnetic force acts becomes smaller than the distance Lb1′ between the second module 31 and the mover 4 before the electromagnetic force acts. With this action, the linear conveyance system 1 can cause the mover 4 to move along a path in a direction in which the magnetic attraction force between the second module 31 and the mover 4 increases. After the path is selected in the branching portion 5, the mover 4 moves by receiving the electromagnetic force from the first module 2 of the non-branching portion 6.

Here, G in Expression (21) represents the size of the step 8 provided in the second module 31. From Expression (24), since |Fa1+Fb1|>|Fa1+Fb1′| is satisfied by providing the step 8, the electromagnetic force that moves the mover 4 in the negative Y direction in the region with the step 8 being present is smaller than the electromagnetic force that moves the mover in the negative Y direction with the step 8 not being present.

FIG. 9 is a cross-sectional view showing a case where the mover travels in the negative X direction and is attracted in the positive Y direction at the branching portion of the linear conveyance system according to Embodiment 2 of the present disclosure. In FIG. 9, it is assumed that, when the mover 4 moves in the negative X direction at the branching portion 5 and the magnetic attraction force Fb3 between the second module 31 and the mover 4 is larger than the magnetic attraction Fa3 between the first module 2 and the mover 4, a path in a direction in which the magnetic attraction force Fa3 increases is selected by a user of the linear conveyance system 1b. At this time, the relationships of the following Expression (27) to Expression (32) are satisfied in the distances Ls of the mover 4 moved by the action of the electromagnetic force, the distances La3 and La4 between the first module 2 and the mover 4 before and after the electromagnetic force acts, the distances Lb3 and Lb4 between the second module 3 and the mover 4 before and after the electromagnetic force acts, the electromagnetic force Fd, the magnetic attraction forces Fa3 and Fa4 before and after the electromagnetic force between the first module 2 and the mover 4 acts, and the magnetic attraction forces Fb3 and Fb4 before and after the electromagnetic force between the first module 2 and the mover 4 acts.

$$\begin{matrix}[ Formula 6 ] & \\ Lb 3 + G = Lb {3}^{′} & ( 27 )\end{matrix}$$

$$La 3 - Lb 3 > Ls > La 3 - Lb {3}^{′} > 0 \qquad ( 28 )$$

$$La 3 - La 4 = Lb 4 - Lb {3}^{′} = Ls \qquad ( 29 )$$

$$Fa 3 + Fb 3 < Fa 3 + Fb {3}^{′} < 0 \qquad ( 30 )$$

$$Fa 3 + Fb {3}^{′} + Fd > 0 \qquad ( 31 )$$

$$Fa 4 + Fb 4 > 0 \qquad ( 32 )$$

The linear conveyance system 1b causes an electromagnetic force to act from the negative Y direction to the positive Y direction in a region after the mover 4 passes through the step 8. A distance Lb3′ between the second module 31 and the mover 4 after the step 8 is passed through is larger than the distance Lb3 between the second module 31 and the mover 4 before the step 8 is passed through. After the step 8 is passed through, a magnetic attraction force Fb3′ becomes small as |Fb3′|<|Fb3|, but from Expression (30), before the electromagnetic force acts, the relationship of Fa3+Fb3′<0 is satisfied, and the magnetic attraction force in the negative Y direction becomes large. When the electromagnetic force F acts, a distance Lb4 between the second module 31 and the mover 4 becomes larger than the distance Lb3′ between the second module 31 and the mover 4 before the electromagnetic force acts. With this action, the linear conveyance system 1b can cause the mover 4 to move along a path in a direction in which the magnetic attraction force between the first module 2 and the mover 4 increases. After the path is selected in the branching portion 5, the mover 4 moves by receiving the electromagnetic force from the first module 2 of the non-branching portion 6.

Here, the state of the mover 4 to which the electromagnetic force acts after the step 8 is passed through in FIG. 8 is the same as the state of the mover 4 before the step 8 is passed through in FIG. 9 and before the electromagnetic force acts, and the relationships of the following Expression (33) and Expression (34) are satisfied.

$$\begin{matrix}[ Formula 7 ] & \\ La 3 = La 2 & ( 33 )\end{matrix}$$

$$Lb 3 = Lb 2 \qquad ( 34 )$$

Further, the state of the mover 4 before the step 8 is passed through in FIG. 8 and before the electromagnetic force acts is the same as the state of the mover 4 to which the electromagnetic force acts after the step 8 is passed through in FIG. 9 and the relationships of the following Expression (35) and Expression (36) are satisfied.

$$\begin{matrix}[ Formula 8 ] & \\ La 4 = La 1 & ( 35 )\end{matrix}$$

$$Lb 4 = Lb 1 \qquad ( 36 )$$

As described above, in the linear conveyance system according to Embodiment 2 of the present disclosure, since |Fa3+Fb3|>|Fa3+Fb3′| is satisfied by providing step 8 as in Expression (27) to Expression (32), the electromagnetic force that moves the mover 4 in the positive Y direction in the region where the step 8 is present is smaller than the electromagnetic force that moves the mover 4 in the positive Y direction in the state where the step 8 is not present.

FIG. 10 is a cross-sectional view showing a case where the mover travels in the positive X direction at the branching portion of the linear conveyance system according to Embodiment 2 of the present disclosure and is attracted in the positive Y direction before passing through the step. In FIG. 10, it is assumed that, when the mover 4 moves in the positive X direction in the branching portion 5 and the magnetic attraction force Fb5 between the second module 31 and the mover 4 is larger than the magnetic attraction force Fa5 between the first module 2 and the mover 4, a path in a direction in which the magnetic attraction force Fa5 increases is selected by a user of the linear conveyance system 1b.

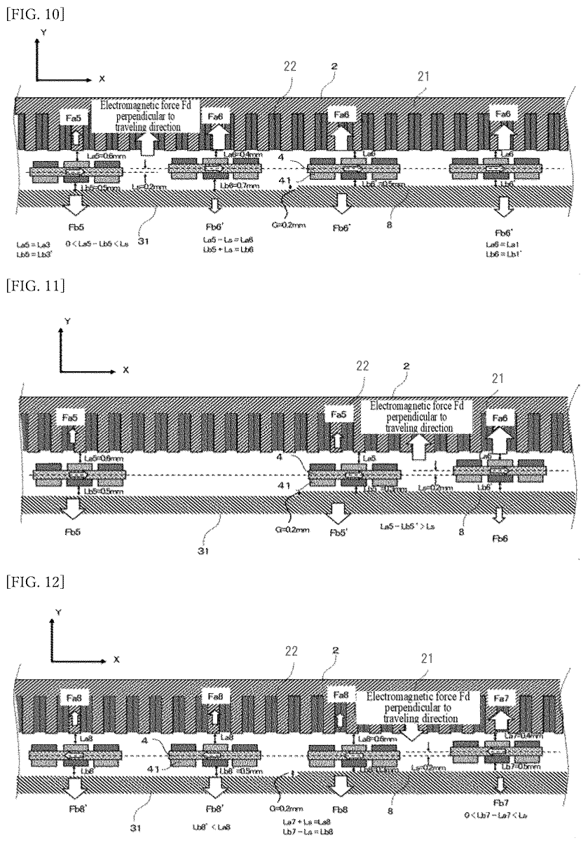

FIG. 11 is a cross-sectional view showing a case where the mover travels in the positive X direction at the branching portion of the linear conveyance system according to Embodiment 2 of the present disclosure, passes through the step, and then, is attracted in the positive Y direction. In FIG. 11, the traveling direction and the attracted direction of the mover 4 are the same as those in FIG. 10, but the position where the mover 4 is attracted by the second module 31 when the mover 4 determines the path in the branching portion 5 is different. At this time, the relationships of the following Expression (37) to Expression (42) are satisfied in the distances Ls of the mover 4 moved by the action of the electromagnetic force, the distances La5 and La6 between the first module 2 and the mover 4 before and after the electromagnetic force acts, the distances Lb5 and Lb6 between the second module 3 and the mover 4 before and after the electromagnetic force acts, the electromagnetic force Fd, the magnetic attraction forces Fa5 and Fa6 before and after the electromagnetic force between the first module 2 and the mover 4 acts, and the magnetic attraction forces Fb5 and Fb6 before and after the electromagnetic force between the first module 2 and the mover 4 acts.

$$\begin{matrix}[ Formula 9 ] & \\ Lb 6 - G = Lb {6}^{′} & ( 37 )\end{matrix}$$

$$La 5 - Lb 5 ' > Ls > La 5 - Lb 5 > 0 \qquad ( 38 )$$

$$La 5 - La 6 = Lb 5 - Lb 6 = Ls \qquad ( 39 )$$

$$Fa 5 + Fb {5}^{′} < Fa 5 + Fb 5 < 0 \qquad ( 40 )$$

$$Fa 5 + Fb 5 + Fd > 0 \qquad ( 41 )$$

$$Fa 6 + Fb 6 > Fa 6 + Fb {6}^{′} > 0 \qquad ( 42 )$$

The linear conveyance system 1b causes an electromagnetic force in the positive Y direction to act in a region before the mover 4 passes the step 8. The distance Lb5 between the second module 31 and the mover 4 before the step 8 is passed through in FIG. 10 is larger than the distance Lb5′ between the second module 31 and the mover 4 in the case when the step 8 is passed through without application of the electromagnetic force in FIG. 11. Since the magnetic attraction force Fb before the step 8 is passed through in FIG. 10 and the Fb5′ in the case when the step 8 is passed through without application of the electromagnetic force in FIG. 11 satisfy |Fb5|<|Fb5′j, the electromagnetic force for moving the mover 4 in the positive Y direction is smaller in the state before the step 8 is passed through. Before the electromagnetic force acts to the mover 4, the relationship of Fa5+Fb5<0 is satisfied from Expression (40), and the magnetic attraction force in the negative Y direction is large. When the electromagnetic force acts, the distance Lb6 between the second module 31 and the mover 4 becomes larger than the distance Lb5 between the second module 31 and the mover 4 before the electromagnetic force acts, and the linear conveyance system 1b can move the mover 4 along a path in a direction in which the magnetic attraction force between the first module 2 and the mover 4 increases. Note that, after the step 8 is passed through, Lb6>Lb6′ is satisfied for the distance Lb6′ between the second module 31 and mover 4, but the magnetic attraction force Fa6 between the first module 2 and the mover 4 is larger than magnetic attraction force Fb6′ between second module and mover 4, and thus the mover does not erroneously move to the path in the direction in which the magnetic attraction force in the negative Y direction increases.

Here, the state of the mover 4 after the step 8 is passed through and before the electromagnetic force acts in FIG. 9 is the same as the state of the mover 4 before the step 8 is passed through and before the electromagnetic force acts in FIG. 10, and the relationships of the following Expression (43) and Expression (44) are satisfied.

$$\begin{matrix}[ Formula 10 ] & \\ La 5 = La 3 & ( 43 )\end{matrix}$$

$$Lb 5 = Lb {3}^{′} \qquad ( 44 )$$

Further, the state of the mover after the step 8 is passed through in FIG. 8 and before the electromagnetic force acts is the same as the state of the mover 4 to which the electromagnetic force acts after the step 8 is passed through in FIG. 10 and the relationships of the following Expression (45) and Expression (46) are satisfied.

$$\begin{matrix}[ Formula 11 ] & \\ La 6 = La 1 & ( 45 )\end{matrix}$$

$$Lb 6 = Lb {1}^{′} \qquad ( 46 )$$

As described above, in the linear conveyance system 1b according to Embodiment 2 of the present disclosure, since the step 8 is provided, |Fa5+Fb5′|>|Fa5+Fb5| is satisfied after the mover 4 passes the step 8, and thus the electromagnetic force that moves the mover 4 in the positive Y direction in the region before the mover 4 passes the step 8 is smaller than the electromagnetic force that moves the mover 4 in the positive Y direction after the mover 4 passes the step 8.

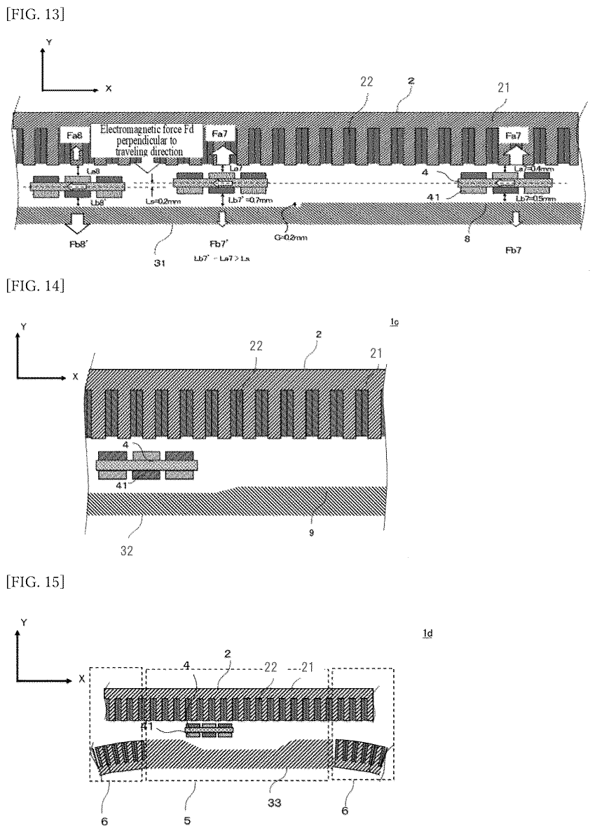

FIG. 12 is a cross-sectional view showing a case where the mover travels in the negative X direction at the branching portion of the linear conveyance system according to Embodiment 2 of the present disclosure and is attracted in the negative Y direction before passing through the step. In FIG. 12, it is assumed that, when the mover 4 moves in the negative X direction at the branching portion 5 and the magnetic attraction force Fa7 between the first module 2 and the mover 4 is larger than the magnetic attraction force Fb7 between the second module 31 and the mover 4, a path in a direction in which the magnetic attraction force Fb7 increases is selected by a user of the linear conveyance system 1b.

FIG. 13 is a cross-sectional view showing a case where the mover travels in the negative X direction at the branching portion of the linear conveyance system according to Embodiment 2 of the present disclosure, passes over the step, and then, is attracted in the negative Y direction. In FIG. 13, the traveling direction and the attracted direction of the mover 4 are the same as those in FIG. 12, but the position where the mover 4 is attracted by the second module 31 when the mover 4 determines the path in the branching portion 5 is different. At this time, the relationships of the following Expression (47) to Expression (52) are satisfied in the distances Ls of the mover 4 moved by the action of the electromagnetic force, the distances La7 and La8 between the first module 2 and the mover 4 before and after the electromagnetic force acts, the distances Lb7 and Lb8 between the second module 3 and the mover 4 before and after the electromagnetic force acts, the electromagnetic force Fd, the magnetic attraction forces Fa7 and Fa8 before and after the electromagnetic force between the first module 2 and the mover 4 acts, and the magnetic attraction forces Fb7 and Fb8 before and after the electromagnetic force between the first module 2 and the mover 4 acts.

$$\begin{matrix}[ Formula 12 ] & \\ Lb 8 + G = Lb {8}^{′} & ( 47 )\end{matrix}$$

$$Lb {7}^{′} - La 7 > Ls > Lb 7 - La 5 \qquad ( 48 )$$

$$La 8 - La 7 = Lb 8 - Lb 7 = Ls \qquad ( 49 )$$

$$Fa 7 + Fb {7}^{′} > Fa 7 + Fb 7 > 0 \qquad ( 50 )$$

$$Fa 7 + Fb 7 + Fd < 0 \qquad ( 51 )$$

$$Fa 8 + Fb 8 < Fa 8 + Fb {8}^{′} < 0 \qquad ( 52 )$$

The linear conveyance system 1b causes the electromagnetic force to act from the positive Y direction to the negative Y direction in a region before the mover 4 passes through the step 8. The distance Lb7 between the second module 31 and the mover 4 before the step 8 is passed through is smaller than the distance Lb7′ between the second module 31 and the mover 4 in the case when the step 8 is passed through without application of the electromagnetic force. About the magnetic attraction force Fb7 before the step 8 is passed through, compared with the magnetic attraction force Fb7′ when the step 8 is passed through without application of the electromagnetic force, |Fb7|>|Fb7′| is satisfied, and thus the electromagnetic force for moving the mover 4 in the negative Y direction is smaller in the state before the step 8 is passed through. Before the electromagnetic force acts to the mover 4, the relationship of Fa7+Fb7>0 is satisfied from Expression (50), and the magnetic attraction force in the positive Y direction is large. When the electromagnetic force acts, the distance Lb8 between the second module 31 and the mover 4 becomes smaller than the distance Lb7 between the second module 31 and the mover 4 before the electromagnetic force acts, and the linear conveyance system 1b can move the mover 4 along a path in a direction in which the magnetic attraction force in the positive Y direction between the second module 31 and the mover 4 increases. Note that, after the step 8 is passed through, Lb8>La8 is satisfied for the distance Lb8′ between second module 31 and the mover 4, but the magnetic attraction force Fa8 between the first module 2 and the mover 4 is smaller than the magnetic attraction force Fb8′ between the second module 31 and the mover 4, and thus the mover 4 does not erroneously move to the path in the direction in which the magnetic attraction force in the positive Y direction increases.

Here, the state of the mover 4 before the electromagnetic force acts and after the step 8 is passed through in FIG. 8 is the same as the state of the mover 4 before the electromagnetic force acts and before the step 8 is passed through in FIG. 12, and the relationships of the following Expression (53) and Expression (54) are satisfied.

$$\begin{matrix}[ Formula 13 ] & \\ La 7 = La 1 & ( 53 )\end{matrix}$$

$$Lb 7 = Lb {1}^{′} \qquad ( 54 )$$

Further, the state of the mover before the electromagnetic force acts and after the step 8 is passed through in FIG. 9 is the same as the state of the mover after the electromagnetic force acts and after the step 8 is passed through in FIG. 12, and the relationships of the following Expression (55) and Expression (56) are satisfied.

$$\begin{matrix}[ Formula 14 ] & \\ La 8 = La 3 & ( 55 )\end{matrix}$$

$$Lb 8 = Lb {3}^{′} \qquad ( 56 )$$

As described above, in the linear conveyance system 1b according to Embodiment 2 of the present disclosure, by providing the step 8, |Fa7+Fb7′|>|Fa7+Fb7| is satisfied after the step 8 is passed through, and the electromagnetic force that moves the mover 4 in the negative Y direction in the region before the step 8 is smaller than the electromagnetic force that moves the mover 4 in the negative Y direction after the step 8 is passed through.

As described above, in the linear conveyance system 1b according to Embodiment 2 of the present disclosure, the second module 31 is made of only a magnetic material and has no coils wound therearound, as in Embodiment 1. Therefore, according to the linear conveyance system 1b of Embodiment 2, even when the conveyance path 7 branches, the second module 3 is used on one side of the side faces of the mover 4 at the branching portion 5, and thus, effects of preventing an increase in weight of the linear conveyance system 1 and preventing the linear conveyance system 1 from increasing in size are achieved, as in Embodiment 1.

Furthermore, in the linear conveyance system 1b according to Embodiment 2 of the present disclosure, since the second module 31 is provided with the step 8 in the direction perpendicular to the traveling direction, when the mover 4 is moved in the negative Y direction, the electromagnetic force that moves the mover 4 in the negative Y direction in the region where the step 8 is present is smaller than the electromagnetic force that moves the mover 4 in the negative Y direction in the state where the step 8 is not present. When the mover 4 is moved in the positive Y direction, the electromagnetic force that moves the mover 4 in the positive Y direction in the region where the step 8 is present is smaller than the electromagnetic force that moves the mover 4 in the positive Y direction in the state where the step 8 is not present. In addition, when the mover 4 is moved in the positive Y direction, due to the step 8 being provided, the electromagnetic force that moves the mover 4 in the positive Y direction in the region before the step 8 is passed through is smaller than the electromagnetic force that moves the mover 4 in the positive Y direction after the step 8 is passed through. Even when the mover 4 is moved in the negative Y direction, the electromagnetic force that moves the mover 4 in the negative Y direction in the region before the step 8 is smaller than the electromagnetic force that moves the mover 4 in the negative Y direction after the step 8 is passed through. As described above, in the linear conveyance system according to Embodiment 2 of the present disclosure, branching can be performed with a smaller electromagnetic force (current), and thus the motor winding or the inverter capacity can be reduced in size.

In addition, the second module 3 may have a shape such that the distance between the first module 2 and the second module 3 in the direction perpendicular to the traveling direction of the mover 4 changes along the traveling direction of the mover 4. At this time, the distance between the first module 2 and the second module 3 in the direction perpendicular to the traveling direction of the mover 4 may be narrowed or widened along the traveling direction.

### Embodiment 3

In Embodiment 3, the same reference numerals are used for the same components as those in Embodiment 1 of the present disclosure, and the description of the same or corresponding parts will be omitted. Hereinafter, a linear conveyance system 1c according to Embodiment 3 will be described with reference to the drawing.

FIG. 14 is a cross-sectional view showing a first module and a second module of a linear conveyance system according to Embodiment 3 of the present disclosure. As shown in FIG. 14, in the linear conveyance system 1c according to Embodiment 3 of the present disclosure, in addition to the configuration of Embodiment 1, a second module 32 is provided with an inclined portion 9 inclined to the direction perpendicular to the traveling direction. The inclined portion 9 is provided, and thus the distance between the second module 32 and the mover 4 is gently changed. Note that the shape of the inclined portion 9 may be inclined with respect to the direction perpendicular to the traveling direction of the mover 4 such that the distance between the inclined portion 9 and the first module 2 decreases or increases.

As described above, in the linear conveyance system 1c according to Embodiment 3 of the present disclosure, the second module 32 is made of only a magnetic material and has no coil wound therearound, as in Embodiment 1. Therefore, according to the linear conveyance system 1c of Embodiment 3, even when the conveyance path 7 branches, the second module 3 is used in the branching portion 5, and thus, effects of preventing an increase in weight of the linear conveyance system 1 and preventing the linear conveyance system 1 from increasing in size is achieved, as in Embodiment 1.

Furthermore, in the linear conveyance system 1e according to Embodiment 3 of the present disclosure, the distance between the second module 32 and the mover 4 is gently changed. Therefore, the magnetic flux distribution between the magnets 41 of the mover 4 and the second module 32 also changes gently, and the cogging thrust generated in the mover 4 can be reduced.

### Embodiment 4

In Embodiment 4, the same reference numerals are used for the same components as those in Embodiment 1 of the present disclosure, and the description of the same or corresponding parts will be omitted. Hereinafter, a linear conveyance system 1d according to Embodiment 4 will be described with reference to the drawings

FIG. 15 is a cross-sectional view showing a first module and a second module of a linear conveyance system according to Embodiment 4 of the present disclosure. As shown in FIG. 15, in the linear conveyance system 1d according to Embodiment 4 of the present disclosure, in addition to the configuration of Embodiment 1, a second module 33 has a symmetrical shape with respect to the axis perpendicular to the traveling direction of the mover 4. FIG. 15 shows, as an example, a case where the inclined portions 9 are symmetrically provided in the second module 33. By forming the second module 33 in a symmetrical shape with respect to the axis perpendicular to the traveling direction of the mover 4, the distance between the first module 2 and the magnets 41 of the mover 4 and the distance between the second module 33 and the magnets 41 of the mover 4 are constant. The symmetrical shape of the second module 33 at this time may be a shape that is line-symmetrical with respect to the axis perpendicular to the traveling direction or may be a shape that is rotationally symmetrical. Note that a plane perpendicular to the traveling direction is assumed, and the shape may be plane-symmetrical with respect to the perpendicular plane, and the symmetrical shape is not limited to these.

As described above, in the linear conveyance system 1d according to Embodiment 4 of the present disclosure, the second module 32 is made of only a magnetic material and has no coil wound therearound, as in Embodiment 1. Therefore, according to the linear conveyance system 1d according to Embodiment 4, even when the conveyance path 7 branches, the second module 3 is used on one side of the side faces of the mover 4 at the branching portion 5, and thus, effects of preventing an increase in weight of the linear conveyance system 1 and preventing the linear conveyance system 1 from increasing in size is achieved, as in Embodiment 1.

Furthermore, in the linear conveyance system 1d according to Embodiment 4 of the present disclosure, since the second module 33 has a shape symmetrical with respect to the axis perpendicular to the traveling direction of the mover 4, the distances between the first module 2 and the magnets 41 of the mover 4 and between the second module 33 and the magnets 41 of the mover 4 are constant, and thus it is possible to reduce the cogging thrust generated when the mover 4 transfers from the non-branching portion 6 to the branching portion 5.

### Embodiment 5

In Embodiment 5, the same reference numerals are used for the same components as those in Embodiment 1 of the present disclosure, and the description of the same or corresponding parts will be omitted. Hereinafter, a linear conveyance system 1e according to Embodiment 5 will be described with reference to the drawing.

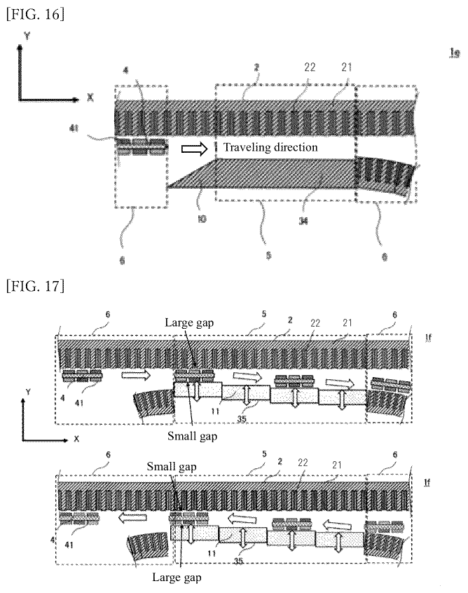

FIG. 16 is a cross-sectional view showing a first module and a second module of a linear conveyance system according to Embodiment 5 of the present disclosure. As shown in FIG. 16, a linear conveyance system 1e according to Embodiment 5 of the present disclosure includes, in addition to the configuration of Embodiment 1, a switching portion 10 between the non-branching portion 6 and the branching portion 5 of the conveyance path 7, in which the distance between the first module 2 and the second module 3 in the direction perpendicular to the traveling direction of the mover 4 decreases as the position changes from the non-branching portion 6 to the branching portion 5. The switching portion 10 is made of a magnetic material and does not include coils. As the magnetic material, a laminated steel plate or the like is used in order to minimize a loss during the drive of the mover 4. The switching portion 10 may be integrated with the second module 34, and the distance between the magnets 41 of the mover 4 and the switching portion 10 may gradually decrease and finally become the same as the distance between the second module 34 of the branching portion 5 and the magnets 41 of the mover 4.

As described above, in the linear conveyance system 1e according to Embodiment 5 of the present disclosure, the second module 34 is made of only a magnetic material without coils, and no coil is wound therearound, as in Embodiment 1. Therefore, according to the linear conveyance system 1e according to Embodiment 5 of the present disclosure, even when the conveyance path 7 branches, the second module 3 is used on one side of the side faces of the mover 4 at the branching portion 5, and thus, effects of preventing an increase in weight of the linear conveyance system 1 and preventing the linear conveyance system 1 from increasing in size is achieved, as in Embodiment 1.

The linear conveyance system 1e according to Embodiment 5 of the present disclosure further includes the switching portion 10 in which the distance between the second module 34 and the mover 4 is decreased when the conveyance path 7 is switched from the non-branching portion 6 to the branching portion 5, and the distance between the second module 34 and the mover 4 is increased when the conveyance path 7 is switched from the branching portion 5 to the non-branching portion 6. Therefore, as the mover 4 moves in the traveling direction, the distance between the switching portion 10 and the magnets 41 of the mover 4 gradually becomes equal to the distance between the second module 34 and the magnets 41 of the mover 4 in the branching portion 5, and thus the permeance changes gently, and the cogging thrust can be reduced.

### Embodiment 6

In Embodiment 6, the same reference numerals are used for the same components as those in Embodiment 1 of the present disclosure, and the description of the same or corresponding parts will be omitted. Hereinafter, a linear conveyance system 1f according to Embodiment 6 will be described with reference to the drawing.

FIG. 17 is a cross-sectional view showing a first module and a second module of a linear conveyance system according to Embodiment 6 of the present disclosure. As shown in FIG. 17, a linear conveyance system 1f according to Embodiment 6 of the present disclosure includes, in addition to the configuration of Embodiment 1, a movable mechanism 11 that is provided in a second module 35, moves the second module 35 in a direction perpendicular to the traveling direction, and changes the traveling direction of the mover 4. By providing the movable mechanism 11, the position of the second module 35 can be changed, and the distance between the second module 35 and the magnets 41 of the mover 4 can be adjusted as desired.

As shown in FIG. 17, in the linear conveyance system 1f according to Embodiment 6 of the present disclosure, when the mover 4 passes through the branching portion 5, the second module 35 is moved in a direction perpendicular to the traveling direction, and thus the path of the mover 4 is selected by the attraction force between the second module 35 and the magnets 41. Although the attractive force in the positive Y direction is large immediately after the mover 4 enters the branching portion 5, the attractive force in the negative Y direction is increased by using the movable mechanism 11 such that the distance to the second module 35 is reduced in accordance with the advance of the mover 4. When the force acting on the entire mover 4 is directed in the negative Y direction, the mover 4 and the second module 35 move together.

In the linear conveyance system 1f according to Embodiment 6 of the present disclosure, a plurality of the second modules 35 may be provided, and movable mechanisms 11 may be provided in the plurality of the second modules 35.

As described above, in the linear conveyance system 1f according to Embodiment 6 of the present disclosure, the second module 35 is made of only a magnetic material and has no coil wound therearound, as in Embodiment 1. Therefore, according to the linear conveyance system 1f according to Embodiment 6, even when the conveyance path 7 branches, the second module 3 is used on one side of the side faces of the mover 4 at the branching portion 5, and thus, effects of preventing an increase in weight of the linear conveyance system 1 and preventing the linear conveyance system 1 from increasing in size is achieved, as in Embodiment 1.

Furthermore, in the linear conveyance system 1f according to Embodiment 6 of the present disclosure, in addition to the configuration of Embodiment 1, the movable mechanism 11 is provided in the second module 35 to cause the second module 35 to move the second module 35 in the direction perpendicular to the traveling direction and change the traveling direction of the mover 4, and thus, since the mover 4 does not use the electromagnetic force from the coil when moving in the direction perpendicular to the traveling direction, the path can be changed without reducing the driving force applied to the mover 4.

Note that the configurations described in the above embodiments are merely examples of the content of the present disclosure, and may be combined with other known techniques. In addition, a part of the configuration can be omitted or changed without departing from the gist of the present disclosure.

### DESCRIPTION OF REFERENCE

1, 1b, 1c, 1d, 1e, 1f: linear conveyance system, 2: first module, 3, 31, 32, 33, 34, 35: second module, 4: mover, 5: branching portion, 6: non-branching portion, 7: conveyance path, 8: step 8, 9: inclined portion, 10: switching portion, 11: movable mechanism, 21: iron core, 22: coils, 23: teeth, 41: magnet 41

1. A linear conveyance system comprising:
a mover having a magnet disposed on side faces thereof; and
a conveyance path in which a first module having a plurality of coils and configured to move the mover by an electromagnetic force of the plurality of coils and a second module formed of a magnetic material without coils are arranged along a traveling direction of the mover, wherein
the conveyance path includes a non-branching portion in which the first module is disposed on one side of the side faces of the mover, and a branching portion in which the first module is disposed on one side of the side faces of the mover and the second module is disposed on the other side of the side faces of the mover.

2. The linear conveyance system according to claim 1, wherein, when the mover travels in the branching portion, a force acting on the mover in a direction perpendicular to the traveling direction is such that an electromagnetic force due to the second module is larger than an electromagnetic force due to the first module, thereby reducing a distance perpendicular to the traveling direction between the mover and the second module.

3. The linear conveyance system according to claim 1, wherein, when the mover travels in the branching portion, a force acting on the mover in a direction perpendicular to the traveling direction is such that an electromagnetic force due to the second module becomes smaller than an electromagnetic force due to the first module, thereby increasing a distance perpendicular to the traveling direction between the mover and the second module.

4. The linear conveyance system according to claim 1, wherein the second module has a shape such that a distance between the first module and the second module in a direction perpendicular to the traveling direction of the mover changes along the traveling direction.

5. The linear conveyance system according to claim 4, wherein the second module is provided with a step in a direction perpendicular to the traveling direction of the mover.

6. The linear conveyance system according to claim 4, wherein the second module is provided with an inclined portion inclined with respect to a direction perpendicular to the traveling direction of the mover.

7. The linear conveyance system according to claim 1, wherein the second module has a shape symmetrical with respect to an axis perpendicular to the traveling direction of the mover.

8. The linear conveyance system according to claim 1, further comprising a switching portion that is provided between the non-branching portion and the branching portion of the conveyance path and in which a distance between the first module and the second module in a direction perpendicular to the traveling direction of the mover decreases as a position changes from the non-branching portion to the branching portion.

9. The linear conveyance system according to claim 1, further comprising a movable mechanism that moves the second module in a direction perpendicular to the traveling direction of the mover.

10. The linear conveyance system according to claim 9, wherein a plurality of the second modules are provided along the traveling direction of the mover, and the movable mechanisms are provided in the respective second modules.
